(19) United States
(12) Patent Application Publication
(10) Pub. No.: US 2026/0360417 A1
(43) Pub. Date: Nov. 12, 2026

(54) METHOD AND DEVICE FOR OPERATING A STORAGE DEVICE, AND STORAGE DEVICE

(71) Applicant: Robert Bosch GmbH, Stuttgart (DE)

(72) Inventors: Taha Soliman, Renningen (DE); Tobias Kirchner, Ludwigsburg (DE)

(21) Appl. No.: 19/125,984

(22) PCT Filed: Nov. 21, 2023
(86) PCT No.: PCT/EP2023/082514

§ 371 Date: Apr. 30, 2025

(30) Foreign Application Priority Data
Dec. 9, 2022 (DE) 10 2022 213 371.4

(51) Int. Cl. G11C 11/412; G06F 17/16; G11C 11/419

(52) U.S. Cl. CPC G11C 11/412; G06F 17/16; G11C 11/419

(57) ABSTRACT

A method for operating a storage device including at least one storage unit, the at least one storage unit having a bistable multivibrator. The method includes: providing a first current which is dependent on a state of the bistable multivibrator, for example characterizable by means of an electric potential of a first circuit node of the bistable multivibrator, and, optionally, evaluating at least the first current.

### FIELD

The present invention relates to a method for operating a storage device.

The present invention also relates to a device for operating a storage device.

The present invention also relates to a storage device.

### SUMMARY

Exemplary embodiments of the present invention relate to a method for operating a storage device comprising at least one storage unit, for example storage cell, the at least one storage unit having a bistable multivibrator, and the method comprising: providing a first current which is dependent on a state of the bistable multivibrator, for example characterizable by means of an electric potential of a first circuit node of the bistable multivibrator, and, optionally, evaluating at least the first current.

Furthermore, the first current is combined with, for example added to, at least one further first current of a further storage unit, for example of the same type.

In further exemplary embodiments of the present invention, it is thereby possible to obtain, e.g., information about a storage content of the at least one storage unit. In further exemplary embodiments, the principle according the embodiments may be applied, e.g., to possibly present multiple storage units of the storage device, whereby, e.g., information about a storage content of the multiple storage units of the storage device is obtained, for example simultaneously, this being usable in further exemplary embodiments, for example to carry out computational operations on the basis of the information obtained.

In further exemplary embodiments of the present invention, the at least one storage unit is designed as a static RAM (random access memory) storage cell or forms a static RAM storage cell.

In further exemplary embodiments of the present invention, the bistable multivibrator has multiple field-effect transistors, e.g., of the MOSFET type.

In further exemplary embodiments of the present invention, the providing of the first current comprises at least one of the following elements: a) providing the first current from a supply which, for example, is external to the bistable multivibrator, b) providing, for example conducting, the first current from the bistable multivibrator, for example from the first circuit node of the bistable multivibrator.

In further exemplary embodiments of the present invention, the method comprises: using at least one provision transistor, for example in the form of a field-effect transistor, for example of the MOSFET type, for the providing.

In further exemplary embodiments of the present invention, the method comprises: connecting a first terminal of a load path of the at least one provision transistor to the supply, for example external supply, connecting a control terminal, for example a gate electrode, of the at least one provision transistor to a or the first circuit node of the bistable multivibrator, and optionally, providing the first current at a second terminal of the load path of the at least one provision transistor.

In further exemplary embodiments of the present invention, the connecting of the first terminal of the load path of the at least one provision transistor to the supply, for example external supply, is carried out via a resistor. Thus, in further exemplary embodiments, the provision transistor is operable in a voltage follower configuration.

In further exemplary embodiments of the present invention, the method comprises: connecting a first terminal of a load path of the at least one provision transistor to a or the first circuit node of the bistable multivibrator, connecting a control terminal, for example a gate electrode, of the at least one provision transistor to the supply, for example external supply, and optionally, providing the first current at a second terminal of the load path of the at least one provision transistor, for example by providing a corresponding electric potential by means of the supply, for example external supply.

In further exemplary embodiments of the present invention, the connecting of the first terminal of the load path of the at least one provision transistor to the first circuit node of the bistable multivibrator is carried out via a resistor.

In further exemplary embodiments of the present invention, the at least one storage unit has two access transistors, each controllable via a first control line, for controllably connecting the bistable multivibrator to two second control lines, for example bit lines, associated with the at least one storage unit, wherein the providing of the first current is accomplished by means of a current-providing means, which is different from the two access transistors. In other words, in further exemplary embodiments the first current is not provided by means of the access transistors.

In further exemplary embodiments of the present invention, it is also possible, however, to provide the first current by means of at least one of the access transistors.

In further exemplary embodiments of the present invention, the method comprises outputting the first current on a first output line. Further exemplary embodiments relate to a device for carrying out the method according to the embodiments.

In further exemplary embodiments of the present invention, the device has a current-providing means which is configured to provide the first current on the basis of the state of the bistable multivibrator, for example on the basis of the electric potential of the first circuit node of the bistable multivibrator.

In further exemplary embodiments of the present invention, at least one provision transistor, for example in the form of a field-effect transistor, for example of the MOSFET type, is provided for the providing of the first current, wherein, for example, the provision transistor is configured a) to provide the first current from a supply which, for example, is external to the bistable multivibrator, and/or b) to provide, for example conduct, the first current from the bistable multivibrator.

Further exemplary embodiments of the present invention relate to a storage device which has at least one storage unit, for example storage cell, the at least one storage unit having a bistable multivibrator, and which has at least one device according to the embodiments.

In further exemplary embodiments of the present invention, the storage device has a control line for controlling a current-providing means of at least one storage unit, for example of multiple storage units, for example of all storage units, of the at least one storage unit.

In further exemplary embodiments of the present invention, at least one resistor, for example controllable resistor, is provided via which the current-providing means of the at least one storage unit, for example of multiple storage units, for example of all storage units, can be controlled by means of the control line.

Further exemplary embodiments of the present invention relate to a computing means, for example vector-matrix multiplication means, having at least one device according to the embodiments and/or at least one storage device according to the embodiments.

Further exemplary embodiments of the present invention relate to a use of the method according to the embodiments and/or of the device according to the embodiments and/or of the storage device according to the embodiments and/or of the computing means according to the embodiments for at least one of the following aspects: a) processing a current associated with the bistable multivibrator, b) ascertaining a sum of first currents each associated with a bistable multivibrator of a respective storage unit, c) providing a computing means, for example for artificial intelligence algorithms, for example for carrying out an inference of an artificial neural network, d) expanding a storage cell, for example conventional storage cell.

Further features, possible applications, and advantages of the present invention emerge from the following description of exemplary embodiments of the present invention, which are shown in the figures. All described or depicted features by themselves or in any combination constitute the subject matter of the present invention, regardless of their formulation or representation in the description or in the figures.

### BRIEF DESCRIPTION OF THE DRAWINGS

FIG. 1 shows schematically, a simplified circuit diagram according to exemplary embodiments of the present invention.

FIG. 2 shows schematically, a simplified flow chart according to exemplary embodiments of the present invention.

FIG. 3 shows schematically, a simplified flow chart according to further exemplary embodiments of the present invention.

FIG. 4 shows schematically, a simplified circuit diagram according to further exemplary embodiments of the present invention.

FIG. 5 shows schematically, a simplified flow chart according to further exemplary embodiments of the present invention.

FIG. 6 shows schematically, a simplified circuit diagram according to further exemplary embodiments of the present invention.

FIG. 7 shows schematically, a simplified flow chart according to further exemplary embodiments of the present invention.

FIG. 8 shows schematically, a simplified circuit diagram according to further exemplary embodiments of the present invention.

FIG. 9 shows schematically, a simplified circuit diagram according to further exemplary embodiments of the present invention.

FIG. 10 shows schematically, a simplified block diagram according to further exemplary embodiments of the present invention.

FIG. 11 shows schematically, aspects of uses according to further exemplary embodiments of the present invention.

### DETAILED DESCRIPTION OF EXAMPLE EMBODIMENTS

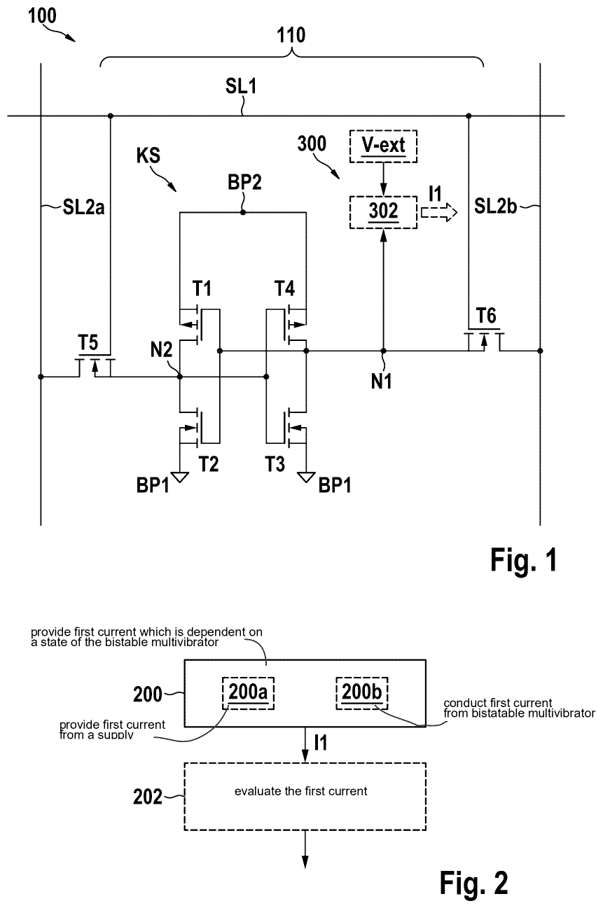

Exemplary embodiments, FIGS. 1 and 2, relate to a method for operating a storage device 100 having at least one storage unit 110, for example storage cell, the at least one storage unit 110 having a bistable multivibrator KS, and the method comprising: providing 200 (FIG. 2) a first current Il which is dependent on a state of the bistable multivibrator KS, for example characterizable by means of an electric potential of a first circuit node N1 (FIG. 1) of the bistable multivibrator KS, and, optionally, evaluating 202 at least the first current I1.

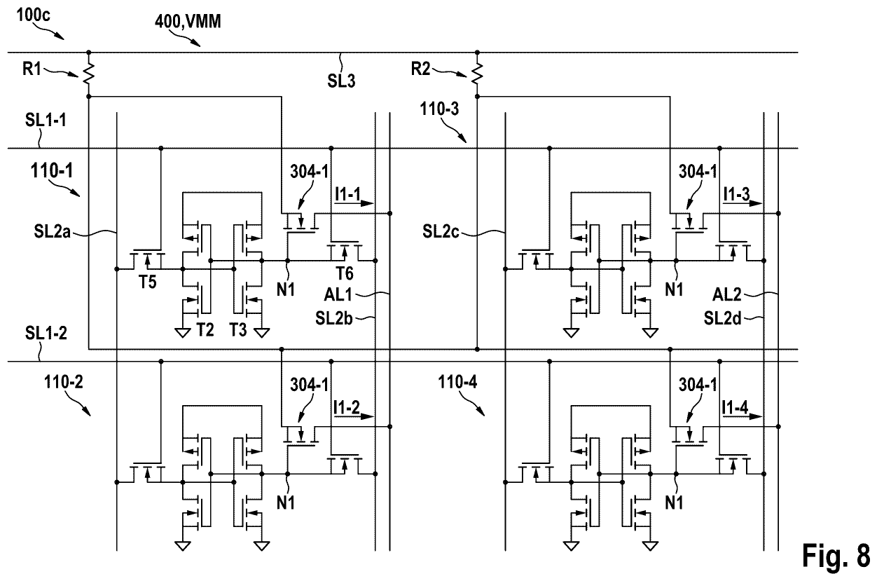

In further exemplary embodiments, it is thereby possible to obtain, e.g., information about a storage content of the at least one storage unit 110. In further exemplary embodiments, the principle according the embodiments may be applied, e.g., to possibly present multiple storage units (see, e.g., FIG. 8) of the storage device, whereby, e.g., information about a storage content of the multiple storage units of the storage device is obtained, for example simultaneously, this being usable in further exemplary embodiments, for example to carry out computational operations on the basis of the information obtained.

In further exemplary embodiments, FIG. 1, the at least one storage unit 110 is designed as a static RAM (random access memory) storage cell or forms a static RAM storage cell.

In further exemplary embodiments, FIG. 1, the bistable multivibrator KS has multiple field-effect transistors T1, T2, T3, T4, e.g., of the MOSFET type, which, e.g., are interconnected in the manner depicted in FIG. 1. The reference sign BP1 symbolizes, by way of example, a first electric reference potential, for example ground potential. The reference sign BP2 symbolizes, by way of example, a second electric reference potential, for example operating voltage potential, which is different from the ground potential BP1.

Element N1 symbolizes, by way of example, a first circuit node of the bistable multivibrator KS at which a storage content of the storage unit 110 is present in the form of an electric potential, e.g., characterizing one of two possible states, e.g., “1” or “0”. In further exemplary embodiments, a state inverse thereto can be present, e.g., in the form of an electric potential, at a second circuit node N2.

In further exemplary embodiments, FIG. 1, the at least one storage unit 110 has two access transistors T5, T6, for example of the MOSFET type. The optional access transistors T5, T6 are controllable, e.g., via a first control line SL1 (which, e.g., can be referred to as “word line”), e.g., for selectively connecting the bistable multivibrator KS to two secondary control lines SL2a, SL2b (which, e.g., can be referred to as “bit lines”) associated with the at least one storage unit 110.

To write to and/or read out the storage unit 110, for example according to a conventional method, the optional access transistors T5, T6 are, e.g., both activated via the first control line SL1, i.e., for example, exposed to a gate-source voltage which is above, e.g., relatively far above, a threshold voltage of the access transistors T5, T6.

In the event of reading out, according to further exemplary embodiments the potential at at least one of the circuit nodes N1, N2 can then be ascertained via the at least one bit line SL2a (or, e.g., via both bit lines SL2a, SL2b), for example measured by a voltage measurement.

In the event of writing, according to further exemplary embodiments a corresponding value can be specified via the at least one bit line SL2a (or, e.g., via both bit lines SL2a, SL2b), e.g., in the form of a respective electric potential to which the bit line(s) is (are) exposed.

In further exemplary embodiments, data can be read from the storage unit 110 and/or written into the storage unit 110 with appropriate control of the access transistors T5, T6, for example by means of the first control line SL1, whereas the providing 200 (FIG. 2) of the first current I1 can be carried out, for example, by means of a device 300 which, for example, is different from the access transistors T5, T6.

In further exemplary embodiments, the device 300 is configured to carry out aspects of the method according to exemplary embodiments, for example to carry out the exemplary sequence according to FIG. 2.

In further exemplary embodiments, FIG. 1, the device 300 has a current-providing means 302 which is configured to provide the first current I1 on the basis of the state of the bistable multivibrator KS, for example on the basis of the electric potential of the first circuit node N1 of the bistable multivibrator KS.

In further exemplary embodiments, FIG. 2, the providing 200 of the first current I1 comprises at least one of the following elements: a) providing 200a the first current I1 from a supply V-ext which, for example, is external to the bistable multivibrator KS (FIG. 1), b) providing, for example conducting, 200b the first current I1 from the bistable multivibrator KS, for example from the first circuit node N1 of the bistable multivibrator KS.

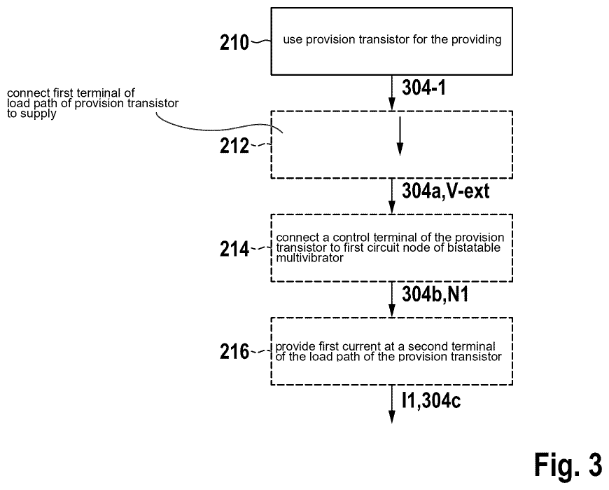

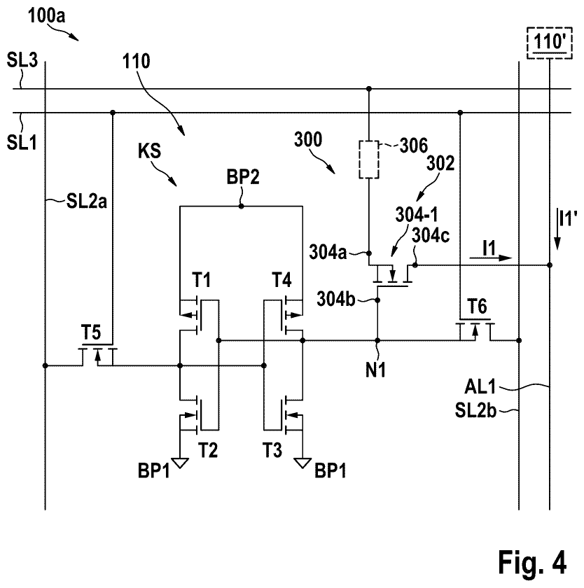

In further exemplary embodiments, FIG. 3, the method comprises: using 210 at least one provision transistor 304-1, for example in the form of a field-effect transistor, for example of the MOSFET type, for the providing; see, e.g., also the exemplary configuration 100a according to FIG. 4.

In further exemplary embodiments, FIGS. 3 and 4, the method comprises: connecting 212 a first terminal 304a of a load path of the at least one provision transistor 304-1 to the supply, for example external supply, V-ext (FIG. 1), e.g., via the third control line SL3 (FIG. 4), connecting 214 a control terminal, for example a gate electrode, 304b of the at least one provision transistor 304-1 to a or the first circuit node N1 of the bistable multivibrator KS, and optionally, providing 216 the first current I1 at a second terminal 304c of the load path of the at least one provision transistor 304-1.

In further exemplary embodiments, FIG. 4, the connecting 212 of the first terminal 304a of the load path of the at least one provision transistor 304-1 to the supply, for example external supply, V-ext is carried out via a resistor 306. Thus, in further exemplary embodiments, the provision transistor 304-1 is operable in a voltage follower configuration.

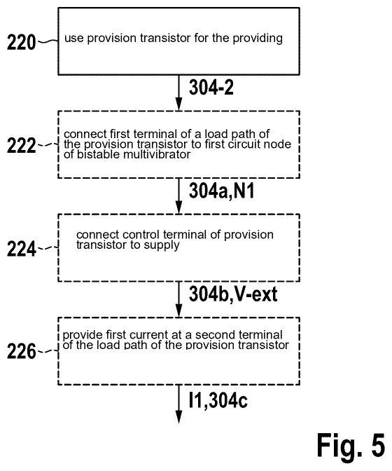

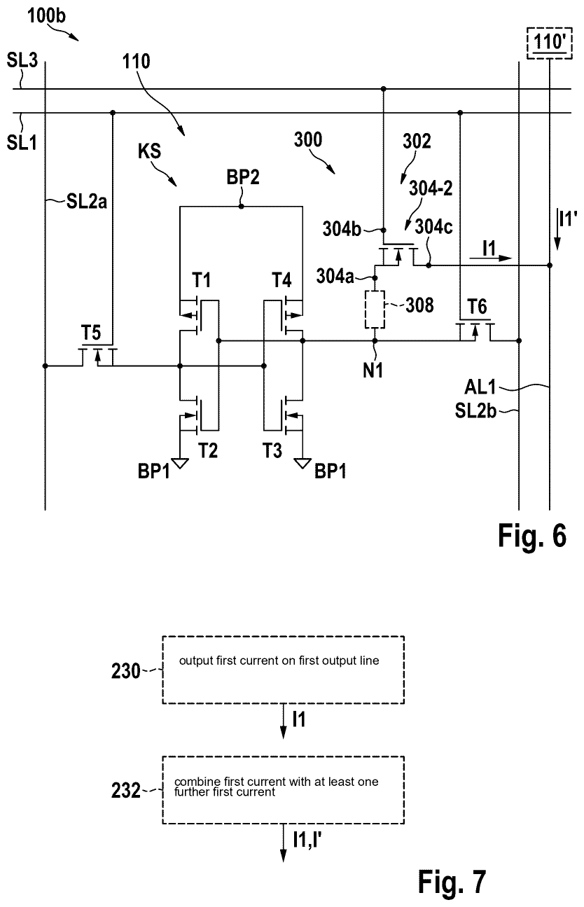

In further exemplary embodiments, FIGS. 5 and 6, the method comprises: using 220 at least one provision transistor 304-2, for example in the form of a field-effect transistor, for example of the MOSFET type, for the providing; see, e.g., also the exemplary configuration 100a according to FIG. 6.

In further exemplary embodiments, FIGS. 5 and 6, the method comprises: connecting 222 a first terminal 304a (FIG. 6) of a load path of the at least one provision transistor 304-2 to a or the first circuit node N1 of the bistable multivibrator KS, connecting 224 a control terminal, for example a gate electrode, 304b of the at least one provision transistor 304-2 to the supply, for example external supply, V-ext (FIG. 1), e.g., by means of the third control line SL3, and optionally, providing 226 the first current Il at a second terminal 304c of the load path of the at least one provision transistor 304-2, for example by providing a corresponding electric potential by means of the supply, for example external supply, V-ext, for example via the third control line SL3.

In further exemplary embodiments, FIGS. 5 and 6, the connecting 222 of the first terminal 304a of the load path of the at least one provision transistor 304-2 to the first circuit node N1 of the bistable multivibrator KS is carried out via a resistor 308.

In further exemplary embodiments, FIGS. 4 and 6, the storage device 100a, 100b is configured to provide, by means of the third control line SL3, a control signal for controlling the provision transistor 304-1, 304-2, for example when the first current Il is to be provided.

In further exemplary embodiments, FIGS. 4 and 6, the storage device 100a, 100b is configured to synchronize the operation of the provision transistor 304-1, 304-2 with at least one further operating mode of the storage unit 110, for example reading and/or writing, e.g., conventional reading and/or writing, for example with corresponding control of at least one of the control lines SL1, SL2a, SL2b.

In further exemplary embodiments, FIGS. 1, 4 and 6, the storage device 100, 100a, 100b is configured to carry out a temperature compensation for the external supply V-ext or for control signals which can be provided via the third control line SL3, e.g., a reference voltage.

In further exemplary embodiments, FIG. 4, for example the multivibrator KS is configured such that, e.g., on the basis of a control signal for the terminal 304a of the provision transistor 304-1, which control signal can be supplied via the third control line SL3, the multivibrator can provide an appropriate gate-source voltage at the first circuit node N1, e.g., for the providing of the first current I1.

In contrast, in the configuration 100b according to FIG. 6, a gate-source voltage for the provision transistor 304-2 can be provided via the third control line SL3, for example from the external supply V-ext (FIG. 1).

In further exemplary embodiments, FIGS. 4 and 6, the storage device 100a, 100b has a first output line AL1 to which and/or via which the first current Il can be output, for example at least at times.

In further exemplary embodiments, FIGS. 4 and 6, the storage device 100a, 100b may have at least one further storage unit 110′ which, in further exemplary embodiments, for example may have a configuration identical or at least similar to the configuration 110 according to FIG. 1.

In further exemplary embodiments, FIGS. 4 and 6, the first current I1 which can be provided by means of the at least one storage unit 110 can, for example via the first output line AL1, be combined with, for example added to, a first current I1′ which can be provided by means of the at least one further storage unit 110′.

In further exemplary embodiments, FIG. 7, the method thus comprises at least one of the following elements: a) outputting 230 the first current I1 on a or the first output line AL1, b) combining 232 the first current I1 with, for example adding it to, at least one further first current I1′, for example of a further storage unit 110′, which, for example, is of the same type or similar or different.

In further exemplary embodiments, the exemplary sequence according to FIG. 7 allows, e.g., aspects of in-memory computing, i.e., a computation within a storage device, since, e.g., first currents I1, I1′ of different storage units 110, 110′ of the storage device 100, 100a, 100b can be added, wherein the first currents I1, I1′ of the different storage units 110, 110′ each depend, e.g., on a storage content of the associated multivibrators KS of the storage units 110, 110′.

In further exemplary embodiments, FIG. 1, the at least one storage unit 110 has the above-described access transistors T5, T6 for controllably connecting the bistable multivibrator KS to two second control lines SL2a, SL2b, for example bit lines, associated with the at least one storage unit, wherein the providing 200 (FIG. 2) of the first current Il is accomplished by means of the current-providing means 302, which is different from the two access transistors T5, T6. In other words, in further exemplary embodiments the first current I1 is provided not by means of the access transistors T5, T6 but rather, e.g., by means of the current-providing means 302, for example having at least one provision transistor 304-1 (FIG. 4), 304-2 (FIG. 6).

In further exemplary embodiments, it is also possible, however, to provide the first current I1 by means of at least one of the access transistors T5, T6. Thus, in some embodiments, for example the current-providing means 302 may be omitted (not shown). In further exemplary embodiments, it is possible that, for the providing 200 of the first current I1, at least one of the access transistors T5, T6 is controlled such that a load path of the at least one access transistor T5, T6 is, for example in comparison with a high-impedance state of the load path of the at least one access transistor T5, T6, at least partially electrically conductive, for example less electrically conductive than in a low-impedance state of the load path of the at least one access transistor T5, T6. This can be achieved, in further exemplary embodiments, for example by exposing a control terminal (e.g., gate electrode) of the at least one of the two access transistors T5, T6 to a control voltage which is less than or equal to a threshold voltage of the at least one access transistor T5, T6, for example via the first control line SL1, for example outside of time periods in which reading or writing, e.g., conventional reading or writing, occurs by means of the at least one access transistor T5, T6.

Further exemplary embodiments, FIG. 1, relate to a storage device 100 which has at least one storage unit 110, for example storage cell, the at least one storage unit 110 having a bistable multivibrator KS, and which has at least one device 300 according to the embodiments.

In further exemplary embodiments, FIG. 1, the storage device 100 has a control line, for example the third control line SL3, for controlling a current-providing means 302 of at least one storage unit, for example of multiple storage units, for example of all storage units, of the at least one storage unit.

In other words, in further exemplary embodiments, FIG. 8, in which a storage device 100c has multiple, in the present case for example four, storage units 110-1, 110-2, 110-3, 110-4, a common, e.g., third, control line SL3 may be provided which supplies provision transistors 304-1 of multiple, for example all, storage units 110-1, 110-2, 110-3, 110-4 of the storage device 100c.

By way of example, the storage units 110-1, 110-2, 110-3, 110-4 of the storage device 100c according to FIG. 8 each have the configuration according to FIG. 4 in which a gate electrode 304b of the provision transistor 304-1 is connected to the first circuit node N1 of the respective bistable multivibrator KS.

By way of example, the storage units 110-1, 110-2, 110-3, 110-4 of the storage device 100c may be organized in matrix form, i.e., in rows and columns, wherein, for example, the storage units 110-1, 110-2 of FIG. 8 form a first column, and wherein, for example, the storage units 110-3, 110-4 of FIG. 8 form a second column. The storage units 110-1, 110-2 of the first column output their respective first current I1-1, I1-2, e.g., onto a common first output line AL1, and the storage units 110-3, 110-4 of the second column output their respective first current I1-3, I1-4, e.g., onto a common second output line AL2.

Element SL1-1 according to FIG. 8 symbolizes a first word line via which, e.g., the access transistors T5, T6 of a first row comprising the storage units 110-1, 110-3 are controllable, for example for reading and/or writing, e.g., conventional reading and/or writing.

Element SL1-2 according to FIG. 8 symbolizes a second word line via which, e.g., the access transistors T5, T6 of a second row comprising the storage units 110-2, 110-4 are controllable, for example for reading and/or writing, e.g., conventional reading and/or writing.

The elements SL2a, SL2b according to FIG. 8 symbolize first bit lines via which, e.g., the storage units 110-1, 110-2 are controllable, for example for reading and/or writing, e.g., conventional reading and/or writing.

The elements SL2c, SL2d according to FIG. 8 symbolize second bit lines via which, e.g., the storage units 110-3, 110-4 are controllable, for example for reading and/or writing, e.g., conventional reading and/or writing.

In further exemplary embodiments, FIG. 8, at least one resistor (in the present case, two resistors) R1, R2 is provided via which the current-providing means, e.g., the provision transistor 304-1, of the at least one storage unit, for example of multiple storage units, for example of all storage units, 110-1, 110-2, 110-3, 110-4 is controllable by means of the third control line SL3. In the present case, for example the provision transistors 304-1 of the storage units 110-1, 110-2 can be controlled by the third control line SL3 via the resistor R1, and for example the provision transistors 304-1 of the storage units 110-3, 110-4 can be controlled by the third control line SL3 via the second resistor R2.

In further exemplary embodiments, the resistors R1, R2 may have equal resistance values.

In further exemplary embodiments, the resistors R1, R2 may have different resistance values.

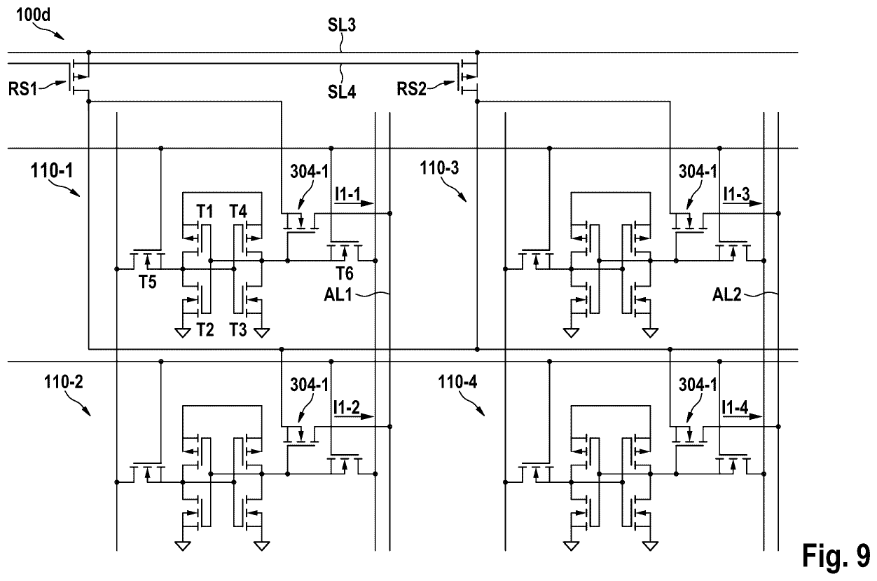

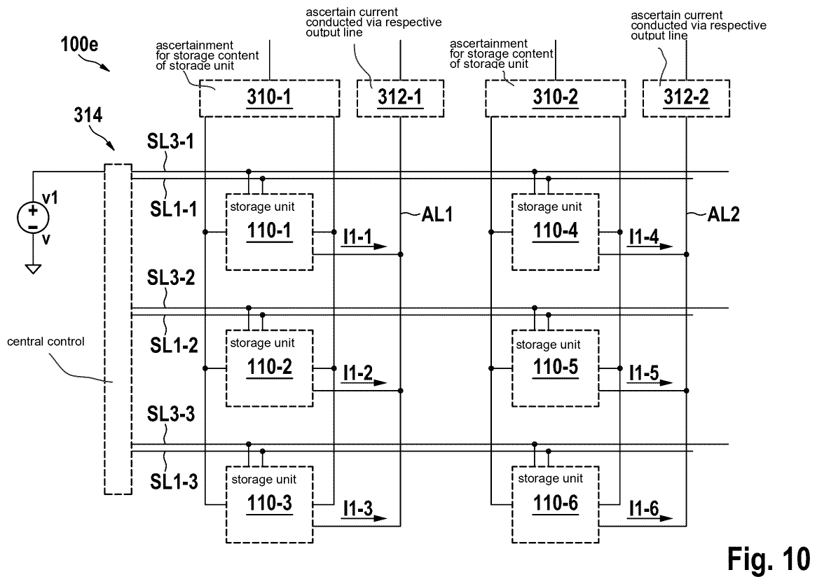

FIG. 9 shows a further configuration 100d of a storage device according to further exemplary embodiments which is similar to the configuration 100c according to FIG. 8. In contrast to FIG. 8, the configuration of FIG. 9 has controllable resistors RS1, RS2 instead of the resistors R1, R2. The controllable resistors RS1, RS2 according to FIG. 9 are, in the present case, by way of example, realized by means of transistors, e.g., MOSFETS, whose load path is connected to the third control line SL3 similarly to the resistors R1, R2 (FIG. 8), but whose gate electrodes can be controlled by means of a fourth control line, in the present case a common fourth control line, SL4, whereby, for example, a resistance value of the load path of the MOSFETs RS1, RS2 can be set.

FIG. 10 schematically shows a simplified block diagram of a storage device 100e according to further exemplary embodiments, which in the present case has, by way of example, six storage units 110-1, 110-2, 110-3, 110-4, 110-5, 110-6, e.g., each similar or identical to the configuration 110 according to FIG. 1 or FIG. 4 or FIG. 6.

The elements 310-1, 310-2 symbolize optional ascertaining means for the storage content of respective storage units, e.g., sense amplifiers, the ascertaining means 310-1 being associated with a first column of storage units 110-1, 110-2, 110-3, and the ascertaining means 310-2 being associated with a second column of storage units 110-4, 110-5, 110-6.

The elements 312-1, 312-2 symbolize optional ascertaining means for the current conducted via the respective output line AL1, AL2, which current corresponds, for example, to a sum of the respective first currents I1-1, I1-2, I1-3 or I1-4, I1-5, I1-6 of an associated column of storage units, which first currents can be provided at least at times by the respective storage units, for example with control of the control lines SL3-1, SL3-2, SL3-3, which in the present case, e.g., are provided row-wise.

The control lines SL1-1, SL1-2, SL1-3, which are likewise provided row-wise (i.e., jointly for all storage units of the same line), can be used, as above for example with reference to the control line SL1 according to FIG. 1, to activate optional access transistors T5, T6 (for example for conventional reading or writing of the respective storage unit) or to deactivate them.

Storage content of respective storage units, the ascertaining means 310-1 being associated with a first column of storage units 110-1, 110-2, 110-3, and the ascertaining means 310-2 being associated with a second column of storage units 110-4, 110-5, 110-6.

Element 314 symbolizes a control means, for example central control means, for providing at least one control signal at least at times, for example for at least one of the control lines SL1-1, SL1-2, SL1-3, SL3-1, SL3-2, SL3-3. By way of example, the control means 314 can be assigned a reference voltage source, e.g., temperature-compensated reference voltage source, V1, from which at least one control signal for at least one of the storage units 110-1, . . . , 110-6 can be conducted or generated in further exemplary embodiments.

Further exemplary embodiments, FIG. 8, relate to a computing means 400, for example vector-matrix multiplication means VMM, having at least one device 300 (FIG. 1) according to the embodiments and/or at least one storage device 100, 100a, 100b, 100c, 100d, 100e according to the embodiments.

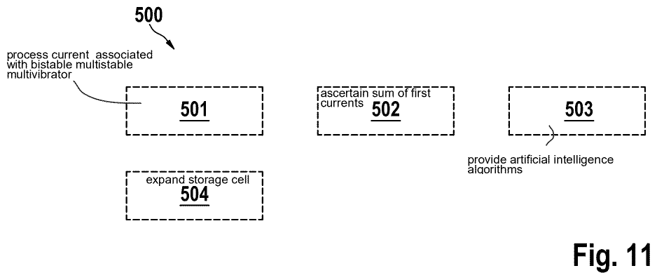

Further exemplary embodiments, FIG. 11, relate to a use 500 of the method according to the embodiments and/or of the device 300 according to the embodiments and/or of the storage device 100, 100a, 100b, 100c, 100d, 100e according to the embodiments and/or of the computing means 400 according to the embodiments for at least one of the following aspects: a) processing 501 a current I1 associated with the bistable multivibrator KS, b) ascertaining 502 a sum of first currents I1, I1′ each associated with a bistable multivibrator of a respective storage unit, c) providing 503 a computing means 400, for example for artificial intelligence algorithms, for example for carrying out an inference of an artificial neural network, for example for in-memory computing, d) expanding 504 a storage cell, for example conventional storage cell.

In further exemplary embodiments, FIG. 10, the functionality of the means 310-1, 312-1 or 310-2, 312-2 may be combined, that is, e.g., one combined means may be provided per column, said combined means being configured to carry out the reading and writing of the respective storage unit, as well as the ascertaining of a sum current of the first currents I1-1, I1-2, I1-3 of the respective column.

In further exemplary embodiments, the means 312-1, 312-2 or the combined means which is described above may be configured, for example, as an analog-digital conversion means, e.g., current-based or current-driven analog-digital conversion means.

In further exemplary embodiments, instead of an analog-digital conversion means 312-1, 312-2, e.g., a or the sense amplifier or the ascertaining means 310-1, 310-2 may also be provided.

In further exemplary embodiments, the sense amplifier or the ascertaining means 310-1, 310-2 may, e.g., have a storage register which can store a threshold value for a detection, the threshold value being, for example, changeable or specifiable such that operating behavior of the ascertaining means 310-1, 310-2, for example for reading the contents of the storage units, can be influenced; in further exemplary embodiments, for example aspects of an activation function of, e.g., artificial neurons can be realized.

In further exemplary embodiments, the activation function controls, e.g., when or under what circumstances, e.g., input data or values of input data, one or more (artificial) neurons or their output or outputs are activated, for example comprising adding the input data and outputting the sum if, for example only if, a specifiable threshold value, for example characterizable by the activation function, is exceeded.

In further exemplary embodiments, for example a threshold voltage for the ascertaining means 310-1, 310-2 may be selected on the basis of the value of the storage register.

In further exemplary embodiments, FIG. 4, the provision transistor 304-1 may be operated in a voltage follower configuration as described above, for example with a digital signal as control signal, wherein the voltage at the source electrode follows, e.g., the voltage at the gate electrode.

In further exemplary embodiments, the provision transistor 304-1 provides, e.g., a voltage drop corresponding to its threshold voltage. The first current I1 which arises is defined, e.g., by the voltage drop across the load path of the provision transistor 304-1.

In further exemplary embodiments, FIG. 4, the optional resistor 306 may be replaced, e.g., by a transistor, e.g., MOSFET, which is operable as a controllable resistor and which, e.g., for comparatively large resistance values, has a comparatively small footprint.

In further exemplary embodiments, FIG. 8, for example for aspects of in-memory computing, a “weight 1” of a “kernel 1” may be stored in a first row of the matrix configuration 100c, and a “weight 2” of the “kernel 1” may be stored in a third row of the matrix configuration 100c. If, for example, a computation is carried out using “kernel 1”, for example only rows 1 and 3 are activated, and no sharing of resistors takes place.

In further exemplary embodiments, FIGS. 8 and 9, the providing 200 (FIG. 2) of the first current can be effected, e.g., by providing a “HIGH” potential on the third control line SL3.

In further exemplary embodiments, for example storage units 110 having six transistors T1, T2, T3, T4, T5, T6 can be expanded or supplemented with the principle according to the present invention.

In further exemplary embodiments, for example storage units having more than the six transistors T1, T2, T3, T4, T5, T6 can also be expanded or supplemented with the principle according to the present invention.

In further exemplary embodiments, for example at least one storage device 100, 100a, 100b, 100c, 100d according to at least one of FIGS. 1, 4, 6, 8 and 9 can also be assigned at least one means 310-1, 312-1, 310-2, 312-2, 314 according to FIG. 10, for example for reading and/or writing, e.g., conventional reading and/or writing, and/or for ascertaining and/or evaluating of the first current of at least one storage unit.

### INFORMATION REGARDING FUNDING AND SUPPORT

The project that led to this application was funded by the ECSEL Joint Undertaking (JU) under Grant Agreement No. 826655. The JU receives support through the Horizon 2020 research and innovation program of the European Union and Belgium, France, Germany, Netherlands, Switzerland.

1-16. (canceled)

17. A method for operating a storage device having at least one storage unit, the at least one storage unit having a bistable multivibrator, the method comprising the following steps:
providing a first current which is dependent on a state of the bistable multivibrator characterized by an electric potential of a first circuit node of the bistable multivibrator; and
combining the first current with at least one further first current of a further storage unit of the same type.

18. The method as recited in claim 17, wherein the at least one storage unit includes at least one storage cell.

19. The method as recited in claim 17, wherein the providing of the first current includes at least one of the following elements: a) providing the first current from a supply which is external to the bistable multivibrator, b) providing the first current from the bistable multivibrator.

20. The method as recited in claim 17, further comprising:
using at least one provision transistor including a field-effect transistor for the providing.

21. The method as recited in recited in claim 20, further comprising:
connecting a first terminal of a load path of the at least one provision transistor to an external supply which is external to the bistable multivibrator; and
connecting a control terminal, for example a gate electrode of the at least one provision transistor to the first circuit node of the bistable multivibrator.

22. The method as recited in claim 21, further comprising:
providing the first current at a second terminal of the load path of the at least one provision transistor.

23. The method as recited in claim 21, wherein the connecting of the first terminal of the load path of the at least one provision transistor to the external supply is carried out via a resistor.

24. The method as recited in claim 20, wherein the providing of the first current includes at least one of the following elements: a) providing the first current from a supply which is external to the bistable multivibrator, b) providing the first current from the bistable multivibrator, and the method further comprises:
connecting a first terminal of a load path of the at least one provision transistor to the first circuit node of the bistable multivibrator;
connecting a control terminal of the at least one provision transistor to the example external supply.

25. The method as recited in claim 24, further comprising:
providing the first current at a second terminal of the load path of the at least one provision transistor.

26. The method as recited in claim 24, wherein the connecting of the first terminal of the load path of the at least one provision transistor to the first circuit node of the bistable multivibrator is carried out via a resistor.

27. The method as recited in claim 17, wherein the at least one storage unit has two access transistors, each controllable via a first control line for controllably connecting the bistable multivibrator to two second control lines which include bit lines associated with the at least one storage unit, and wherein the providing of the first current is accomplished using a current-provider, which is different from the two access transistors.

28. A device configured to operate a storage device having at least one storage unit, the at least one storage unit having a bistable multivibrator, the device configured to:
provide a first current which is dependent on a state of the bistable multivibrator characterized by an electric potential of a first circuit node of the bistable multivibrator; and
combine the first current with at least one further first current of a further storage unit of the same type.

29. The device as recited in claim 28, wherein the device includes a current-provider configured to provide the first current based on the state of the bistable multivibrator which characterizes the electric potential of the first circuit node of the bistable multivibrator.

30. The device as recited in claim 28, wherein at least one provision transistor in the form of a field-effect transistor is provided for the providing of the first current, the provision transistor is configured: a) to provide the first current from a supply to the bistable multivibrator, and/or b) to provide the first current from the bistable multivibrator.

31. A storage device, comprising:
at least one storage unit having a bistable multivibrator; and
at least one device configured to operate a storage device having at least one storage unit, the at least one storage unit having a bistable multivibrator, the device configured to:
provide a first current which is dependent on a state of the bistable multivibrator characterized by an electric potential of a first circuit node of the bistable multivibrator, and
combine the first current with at least one further first current of a further storage unit of the same type.

32. The storage device as recited in claim 31, having a control line configured to control a current-provider of at least one storage unit of the at least one storage unit.

33. The storage device as recited in 32, wherein at least one resistor is provided via which the current-provider of the at least one storage unit is controllable using the control line.

34. A vector-matrix multiplication devices (VMM), comprising a storage device including:
at least one storage unit having a bistable multivibrator; and
at least one device configured to operate a storage device having at least one storage unit, the at least one storage unit having a bistable multivibrator, the device configured to:
provide a first current which is dependent on a state of the bistable multivibrator characterized by an electric potential of a first circuit node of the bistable multivibrator, and
combine the first current with at least one further first current of a further storage unit of the same type.

35. The method according to claim 17, wherein the method is used for at least one of the following aspects: a) processing a current associated with the bistable multivibrator, b) ascertaining a sum of first currents each associated with a respective bistable multivibrator of a respective storage unit, c) providing a computer for artificial intelligence algorithms, for carrying out an inference of an artificial neural network, d) expanding a storage cell.
